(19) United States
(12) Patent Application Publication
(10) Pub. No.: US 2014/0170792 A1
(43) Pub. Date: Jun. 19, 2014

(54) FORMING THIN FILM VERTICAL LIGHT EMITTING DIODES

(71) Applicant: Nthdegree Technologies Worldwide Inc., Tempe, AZ (US)

(72) Inventor: Bradley S. Oraw, Chandler, AZ (US)

(73) Assignee: Nthdegree Technologies Worldwide Inc., Tempe, AZ (US)

(21) Appl. No.: 14/103,464

(22) Filed: Dec. 11, 2013

Related U.S. Application Data
(60) Provisional application No. 61/738,522, filed on Dec. 18, 2012.
(60) Provisional application No. 61/738,513, filed on Dec. 18, 2012.
(60) Provisional application No. 61/783,827, filed on Mar. 14, 2013.

(51) Int. Cl. H01L 33/24; H01L 33/08

(52) U.S. Cl. CPC H01L 33/24; H01L 33/08
USPC 438/34

(57) ABSTRACT

A thin film vertical light emitting diode (VLED) structure and process are described. Features of the design include the following: bonding multiple smaller diameter LED wafers to a larger diameter carrier wafer, which reduces the per LED fabrication cost; using thin film techniques to metalize the anode and cathode and using respective annealing steps prior to photolithography patterning of LED structures; enabling the thin film process by semi-permanent bonding techniques which provide thermal and chemical stability, while allowing bond release at an opportune time by thermal, optical, or chemical means; using epitaxial substrate removal techniques to separate the entire LED film from its growth substrate; and patterning various vertical LED devices which can emit light from the n-type side (cathode), p-type side (anode), side wall, or a combination of the surfaces by using mirror layers and electrically conductive and optically transmissive layers.

### CROSS-REFERENCE TO RELATED APPLICATIONS

This application is based, in part, on U.S. provisional application Ser. No. 61/738,522, filed Dec. 18, 2012, entitled Thin Film Processing of a Metal-VLED-Metal Stack, by Bradley Oraw, assigned to the present assignee and incorporated herein by reference.

This application is also based, in part, on U.S. provisional application Ser. No. 61/738,513, filed Dec. 18, 2012, entitled Bonding Multiple Smaller Diameter Wafers to a Larger Diameter Wafer, by Bradley Oraw, assigned to the present assignee and incorporated herein by reference.

This application is also based, in part, on U.S. provisional application Ser. No. 61/783,827, filed Mar. 14, 2013, entitled Thin Film Vertical Light Emitting Diode Structure and Method of Manufacture, by Bradley Oraw, assigned to the present assignee and incorporated herein by reference.

### FIELD OF THE INVENTION

This invention relates to forming vertical LEDs and, in particular, to various processes for forming such LEDs.

### BACKGROUND

The substrate wafers for forming gallium-nitride based LEDs, such as for forming blue LEDs, are typically sapphire. Such substrates are small (e.g., 4 inches or less) compared to silicon substrate wafers (e.g., 12 inches) used to form integrated circuits. The processing cost for each GaN LED die can be greatly reduced if more LED dies can be supported by a single wafer, since the processing cost does not significantly change with the size of the wafer.

Other issues with conventional fabrication techniques for LEDs include: 1) difficulties with dealing with 2-sided photolithography to form a vertical LED; and 2) difficulties in handling the thin LED semiconductor wafers if the growth substrate is to be removed. Easing such difficulties would reduce the cost of the LEDs and increase the yield.

Further, the processes for forming conventional LEDs constrain the light emission surface to the side opposite the growth substrate. It would be desirable to be able to select whether the light emission surface is the cathode side or the anode side.

### SUMMARY

Various thin film vertical light emitting diode (VLED) structures and processes are described which reduce LED fabrication costs and improve the yield.

The key innovations are

1) bonding multiple smaller diameter wafers to a larger diameter wafer, which reduces the per LED fabrication cost;

2) using thin film techniques to metalize the anode and cathode, and using respective annealing steps prior to photolithographic patterning of the device structures;

3) enabling the thin film process by innovative semi-permanent bonding techniques, which provide thermal and chemical stability, while allowing bond release at an opportune time by thermal, optical, or chemical means;

4) using novel epitaxial substrate removal techniques to separate the entire LED film from its growth substrate, such as separating GaN semiconductor layers from a sapphire substrate wafer; and

5) patterning vertical LED devices which can emit light from the n-type side (cathode), p-type side (anode), side walls, or a combination of the surfaces by using minor layers and electrically conductive and optically transmissive layers.

### BRIEF DESCRIPTION OF THE DRAWINGS

FIG. 1 is a top down view of four shaped LED wafers bonded to a larger carrier (or handle) wafer for simultaneously processing.

FIG. 2 is a top down view of two LED wafers bonded to a larger carrier (or handle) wafer for simultaneously processing.

FIG. 3 is a simplified cross-sectional view of a conventional lateral LED.

FIG. 4 is a simplified cross-sectional view of a conventional vertical LED.

FIGS. 5A-5F are cross-sectional views of an LED wafer undergoing a conventional process for forming vertical LEDs, requiring 2-sided photolithography.

FIGS. 6A-6H are cross-sectional views of an LED wafer undergoing a process for forming vertical LEDs in accordance with an embodiment of the invention, requiring only 1-sided photolithography.

FIGS. 7A-7E are cross-sectional views of an LED wafer undergoing a process for forming vertical LEDs in accordance with another embodiment of the invention, requiring only 1-sided photolithography.

FIGS. 8A-8C schematically illustrate a handle wafer bonding and de-bonding technique in accordance with one embodiment of the invention.

FIGS. 9A-9C schematically illustrate a handle wafer bonding and de-bonding technique in accordance with another embodiment of the invention.

FIGS. 10A-10C schematically illustrate a handle wafer bonding and de-bonding technique in accordance with another embodiment of the invention.

FIGS. 11A-11D schematically illustrate a handle wafer bonding and de-bonding technique in accordance with another embodiment of the invention.

FIGS. 12A-12D schematically illustrate a handle wafer bonding and de-bonding technique in accordance with another embodiment of the invention.

FIGS. 13A and 13C schematically illustrate a handle wafer bonding and etching technique in accordance with another embodiment of the invention.

FIG. 13B is a top down view of the LED semiconductor layers in the wafer structure after the handle wafer of FIG. 13A is bonded to the LED wafer.

FIG. 13D is a top down view of the LED semiconductor layers in the wafer structure of FIG. 13C after the edges have been etched back.

FIGS. 14A-14D are cross-sectional views of an LED wafer undergoing a preparation process prior to removing the LED layers from the sapphire growth substrate by spalling, in accordance with an embodiment of the invention.

FIGS. 15A-15C are top down views of GaN layers on an LED wafer being shaped to be supported on a larger wafer, where the shape affects the stresses involved during the spalling process, in accordance with one embodiment of the invention.

FIG. 16 schematically illustrates a process for roughly grinding the growth substrate to a first thickness, followed by using a more controlled etching tool, such as sand blasting, to remove the remainder of the substrate while optically measuring the thickness of the substrate, in accordance with one embodiment of the invention.

FIGS. 17A-17C schematically illustrate a grinding or polishing process for removing the growth substrate from the LED layers, in accordance with one embodiment of the invention.

FIGS. 18A-18L are cross-sectional views of different configurations of vertical LEDs having different characteristics, where the light directionality (through the anode side or cathode side) can be easily configured, in accordance with one embodiment of the invention.

FIG. 19 lists process flow steps for forming vertical LEDs using a single handle wafer, in accordance with one embodiment of the invention.

FIGS. 20A-20K schematically illustrate layers of an LED wafer undergoing the process flow of FIG. 19, in accordance with one embodiment of the invention.

FIG. 21 is a perspective view of a single, microscopic LED die that is configured for being printed as an LED ink, in accordance with one embodiment of the invention.

FIG. 22 is a top down view of an array of the LED dies of FIG. 21 supported by a handle wafer prior to singulation, in accordance with one embodiment of the invention.

FIG. 23 is a perspective view of the LED dies of FIG. 22, in accordance with one embodiment of the invention.

Elements that are similar or identical in the various figures are labeled with the same numeral.

### DETAILED DESCRIPTION

### Problem 1—Per Wafer LED Device Processing Costs

Conventional “large” die (0.01-1 mm²) LED devices can be fabricated by using only a few photolithographic steps to pattern features. Micro-die (100-1000 um²) LED devices typically require additional photolithography steps and smaller critical dimensions to create the necessary features. In general, photolithography steps are costly. Further, alignment of multiple lithographic layers compounds the cost. As such, the cost of the device fabrication steps can easily exceed the cost of the starting LED epitaxial wafer. Therefore, even if the cost of the starting LED epitaxial wafer is reduced, the per-wafer finished cost will be lower bound by the device processing costs. As such, it is important to reduce the cost of LED fabrication.

### Solution 1—Bonding Multiple Smaller Diameter to a Larger Diameter Wafer

One solution to the above-identified problem is to bond multiple smaller-diameter LED wafers to a single larger diameter wafer (a handling wafer) to lower minimum per-wafer cost. The combined area of the smaller wafers increases the per-wafer device area, reducing the per-device process cost by the ratio of the large wafer area to the small wafer area. For example, common LED epitaxial growth can be successfully achieved on a 100 mm diameter substrate (e.g., sapphire, SiC, etc.). 200 mm semiconductor device processing equipment is plentiful and fast, hence, economical. Therefore, mounting four 100 mm wafers on a 200 mm wafer can greatly reduce the per-device processing cost.

Since the original 100 mm LED wafers are circular, the area of the 200 mm wafer may be most optimally used by shaping four 100 mm wafers to maximize the number of LED dies on the 200 mm wafer. Such shape modification thus allows an increase in the ratio of the large wafer area to the small wafer area. Shaping may be my means of sawing or other technique to effective form tiles of the smaller wafers for bonding to the larger wafer.

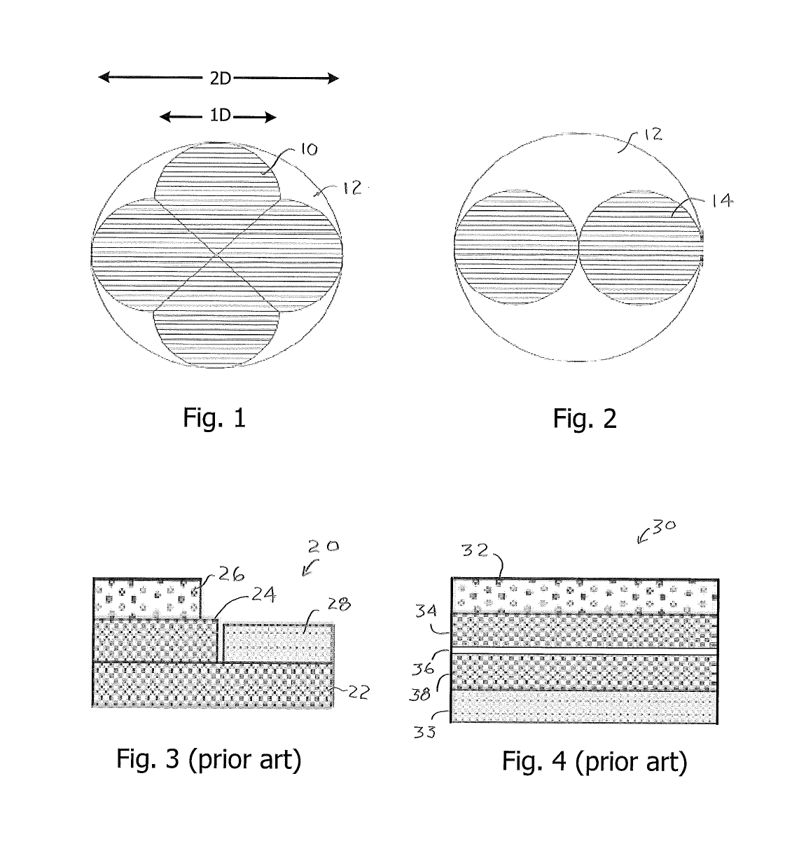

FIG. 1 shows an example of bonding shaped smaller LED wafers 10 to a larger wafer 12. The wafers 10 are identical. The wafer 12 may be any material, including silicon, glass, etc. The wafer 12 can also be formed of unconventional materials, such as, for example, epoxy, wax, high density sapphire, etc. The LED wafers 10 may or may not include a support substrate and comprise a stack of thin GaN layers.

In FIG. 1, the wafers 10 with diameter D are modified in shape to allow more efficient tiling onto the wafer 12 with diameter 2D, allowing (in this example) four smaller wafers 10 to be bonded to the larger wafer 12, and thus create a much greater total functional LED wafer area. The wafers 10 are each cut to form a 90 degree edge so as to have the corner substantially at the center of the large wafer 12 and the rounded edge aligned with edge of the large wafer 12. The flat edges of the wafers 10 substantially abut each other. About 82% of the large wafer 12 is utilized. Since processing the single wafer 12 effectively processes almost 4 smaller wafers 10 without any additional cost, about 60% more LED wafer area is processed per wafer run compared to processing the single wafers 10, resulting in a substantial processing cost reduction.

FIG. 2 shows a less efficient example of bonding two identical smaller wafers 14 to the larger wafer 12. In this case, the wafers 14 with diameter D are not modified in shape before bonding to the wafer 12 with diameter 2D, allowing only two smaller wafers 14 to be bonded to the larger wafer 12, resulting in a smaller increase in total functional LED wafer area compared to FIG. 1.

Bonding of the wafers 10/14 to the wafer 12 may be done using well known temporary adhesive bonds, where the bonds may be dissolved by a solution or UV, or melted for de-bonding. A metal-metal bond can also be used. If mechanical bonds are inadequate in terms of bond strength stability, compatibility, and cost of de-bonding, an anodic bond (using electromagnetic fields) can also be used. Other bonds could be used, and the choice of bond will determine the ease of de-bonding. Some preferred embodiments exploit semi-permanent bonding. The simplicity and compatibility of the de-bonding mechanism is critical to such a device process.

Some embodiments use high temperature annealing of p-GaN metallization prior to bonding and the proposed sawing/shaping. Other high temperature processes could be performed prior to sawing and bonding.

Some typical dimensions may be as follows. 6″ LED wafers could be bonded to a 12″ (˜300 rnrn) handle wafer, requiring 12″ processing equipment. A typical LED wafer is 4″, so the initial focus would be 8″ handle wafers and 8″ processing equipment. Other sample embodiments can tile 4″ wafers on 12″ handle wafers. 2″ LED wafers are also very common, which can be tiled on 4″, 6″, 8″, 12″, or any other larger sized handle wafer. 8″ LED wafers could be tiled onto 18″ handle wafers. For small LED wafers (e.g., 2″) tiled onto large handle wafers (e.g., 12″), substantial processing cost savings are achieve even with no shaping of the LED wafers.

A GaN or other III-V handle wafer is possible. However, cost is a factor. Practical embodiments use sapphire, quartz, glass, and Si handle wafers, but other material is certainly possible. The handle wafers may be reusable. The choice of handle material is selected for thermal coefficient of expansion (TCE) compatibility with the LED wafer during bonding and subsequent processing. The surface properties, such as surface energy, may affect the strength of the bond. Optical transmission or opacity can be exploited during bonding and de-bonding.

For IR and long wavelength red LEDs (e.g., HgCdTe or PbSnTe), selecting appropriate handle wafers will be necessary. The device process of non-GaN LEDs will be somewhat different for semiconductor contact metallization. Post-bond processing in such embodiments will generally have necessarily different parameters, and the handle wafer might require other properties to fit with a non-GaN LED process.

Crystallinity of the handle wafer is advantageous for strength of the bond, compatibility with subsequent processing, ease of de-bonding, and handle recycling. Some sample process embodiments include drilling holes in handle wafers to improve bond strength and enable and/or accelerate de-bonding. The crystal structure or lack thereof will affect the ability to drill holes and the brittleness of the handle wafer with possibly rough holes.

If the handle wafer can be reused, the cost of the handle material can be amortized across several runs, so a robust handle is desired. A brittle handle will be more likely to break.

Borosilicate and other glass handle wafers are also used. This glass can be considered as fused. Traditional pulled material with wire saw wafering can have advantages of homogeneity and better total thickness variation (TTV) and planarity. Thickness variation and planarity of handle wafers is particularly important for bond strength and uniformity and subsequent mechanical processing, such as back-grinding, lapping, and polishing.

Some sample embodiments of present inventive processes use grind and CMP to prepare the handle wafer, to achieve the desired TTV and planarity of handle wafers. Contaminants are of concern if subsequent processing thermally activates a significant diffusion of contaminant species into sensitive device layers. In general, the device processes have been designed with the lowest temperature range and appropriate diffusion barriers between incompatible or sensitive layers, such as metal-semiconductor interfaces and harmful intermetallics.

Some material systems can also use zone-refined material (for achieving purity), rather than material formed using the conventional Czochralski process, for the device wafers. This choice affects the starting shape. Melting and extruding through a particularly shaped aperture can potentially avoid sawing. However, epitaxial growth is required on such a shape-refined substrate. Typically, epitaxial LED growth is done on circular substrates. The epitaxial process is very sensitive to temperature. If an asymmetric substrate is used, then the epitaxial reactor, and specifically the heat transfer, must be optimized for the irregular substrate shape.

The LED wafers may have any advantageous shape. Hexagonal tiling can achieve high packing density (as compared with circular tiling), as can square tiling. There might be a cost advantage in terms of modification yield (in that there is only one chance of breaking the wafer during the shape modification process) and the time required to modify the shape. For example, a process requiring more saw passes is more expensive and more likely to damage the interior of the wafer, but an area gain could result in some embodiments which form hexagons rather than pie shapes. Scribing geometries can also be affected by crystal orientation of different semiconductor materials.

Similarly, the handle wafer does not have to be circular, but can be any other suitable shape to maximize efficiency, such as a square.

### Problem 2—Lateral Devices or Two-Sided Lithography

Generally, thin film vertical light emitting diode (VLED) structures and processes are designed to reduce LED fabrication costs and enable ideal device structures having vertical current paths.

FIG. 3 is a cross-sectional view of a simplified prior art lateral LED 20. Standard LED epitaxial growth starts with an n-type layer 22 over a growth substrate (not shown), followed by a thin light emitting active region (not shown), and ending with a p-type layer 24. This means that the n-type material is buried in the stack. In order to make electrical contact to the n-type layer 22, a mesa etch starting from the p-type surface is used to etch though the p-type layer 24 and active region to expose the n-type layer 22.

An anode electrode 26 and cathode electrode 28 are then patterned to make electrical contact to the respective semiconductor layers. This creates a lateral LED device (i.e., a device requiring lateral current flow). Current from the p-type layer 24 is injected through the light emitting active region and into the n-type layer 22, where it spreads laterally to the cathode electrode 28. Such a lateral current flow increases series resistance, depending on the thickness and mobility of the n-type layer 22.

Common GaN LED epitaxial layers include an approximately 3 um n-type GaN layer. Commonly, n-type doping concentration is constrained in order to preserve crystal quality. This limitation consequently constrains the lateral sheet resistance of the n-type layer 22. Power efficiency of the device decreases as power is lost in the lateral resistance.

Lateral resistance of the p-type layer 24 is similarly constrained. Typically, the p-type layer 24 is an order of magnitude thinner than the n-type layer 22. Additionally, electrical activation of p-type doping such as Mg in p-type GaN is difficult, so p-type mobility can be very low. Hence p-type lateral resistance is quite high. Commonly, a low resistance current spreading layer such as a metal or a conductive oxide is deposited on top of the p-type surface. If light is to exit through the p-type layer 24, the anode electrode 26 may have a small area, and the current spreading layer may be in the form of thin metal fingers, a radial pattern, dots, or other pattern to allow the light to exit. The parallel resistance of the p-type and spreading layers approaches the resistance of the n-type layer 22.

The difference between the sheet resistance of the n-type layer 22 and the combined p-type/spreading layer causes an imbalance in the current injected into the active region. When current is imbalanced, local current density increases. Effectively, the current is confined to a smaller area than the total active area. Internal quantum efficiency decreases with current density. Therefore current imbalance will decrease overall efficiency, because most of the current will inject at a high current density. Hence, considering high lateral resistance and current imbalance, a lateral LED is not an ideal device.

FIG. 4 is a cross-sectional view of a simplified prior art vertical LED 30, having vertical current flow, with the anode electrode 32 and cathode electrode 33 on opposite sides of the device. A vertical LED reduces the problems with lateral current flow through the n-type layer since the current flows vertically. The basic epitaxial layers include a p-type layer 34, an active region 36, and an n-type layer 38 grown over a growth substrate, which has been removed. If light is to exit the p-type layer 34, the anode electrode 32 may have a small area, and the current spreading layer may be in the form of thin metal fingers, a radial pattern, dots, or other pattern over the p-type layer 34 to allow the light to exit. The cathode electrode 33 may include a reflective layer.

Current from the p-type layer 34 injects vertically through the active region 36 and continues vertically through the n-type layer 38 where it exits vertically though the cathode electrode 33.

Since both the p-type and n-type layers have metal contacts on their surfaces, the n-type surface must be exposed during the fabrication process. This requires removing the epitaxial growth substrate (e.g., sapphire) and any buffer material between the n-type layer 38 and the substrate.

In a conventional process, prior to removing the growth substrate (providing mechanical stability to the thin GaN layers), a p-metal contact layer (not shown) is deposited on the p-type layer 34. The contact layer acts act as an ohmic interface and diffusion barrier between the p-type layer 34 and the anode electrode 32. The anode electrode 32 (a metal layer) is then deposited. The metal layers are patterned to allow light to exit the p-type surface while spreading current across the p-type surface. The individual LED die perimeters within the wafer are then defined by etching, sawing, or by other means to create trenches, which further patterns the p-metal contact layer and the anode electrode layer. Then, the p-side surface is bonded to a temporary handle wafer or carrier substrate for mechanical stability. The growth substrate is then removed, such as by laser lift-off or grinding to expose the n-type layer 38. After removing the growth substrate, the n-metal contact layer and cathode electrode layer are deposited and patterned. Hence, photolithography (masking, etching, etc.) must be performed on both sides of the LED semiconductor stack, which is problematic, and planarity of the n-type surface after substrate removal is difficult to achieve. Small features may not resolve if adequate planarity is not achieved.

Further, the alignment of the LED devices (dies) may shift during the substrate removal process, so that the alignment of n-type surface features (achieved by photolithography) may be compromised.

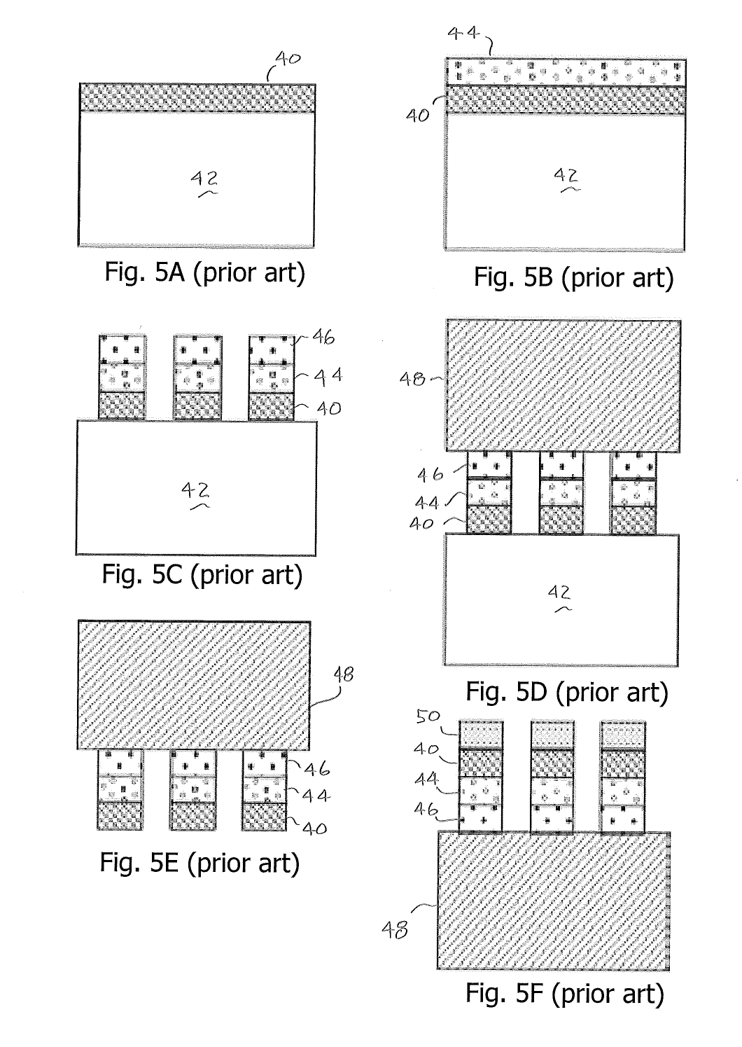

FIGS. 5A-5F illustrate one prior art process flow for forming a vertical LED using two-sided photolithography.

FIG. 5A shows the LED semiconductor stack 40, which includes the p-type layer, the active region, and the n-type layer, plus any buffer layers, epitaxially grown over a growth substrate 42.

FIG. 5B shows the metallization of the p-type layer with a metal contact layer 44.

FIG. 5C shows the anode electrode layer 46 deposited. The metal layers 44/46 are patterned (e.g., to form thin fingers, etc.) to allow the light to escape the p-type layer while the layers 44/46 spread current across the p-type surface for each individual LED die area.

Also in FIG. 5C, the device layers are patterned using photolithography, and die isolation is created (e.g., by sawing, etching, etc.) by forming trenches.

In FIG. 5D, a handle wafer 48 is bonded to the p-side of the stack.

In FIG. 5E, the LED growth substrate 42 is removed to expose the n-type layer surface.

In FIG. 5F, the n-type layer is metalized with a contact layer and cathode electrode layer 50 using backside photolithographic patterning.

The individual LEDs are then separated from the handle wafer 48 by de-bonding.

Depending on the bonding material, the de-bonding may be by dissolving the adhesive, melting the adhesive, UV exposure, neutralizing any electrostatic binding forces, grinding away the handle wafer, or other means.

As described above, the conventional processes for vertical LED fabrication have significant shortcomings. Vertical LEDs require complex and difficult two-sided lithography. Lateral LEDs, which can be fabricated more simply without requiring two-sided lithography, have significant operational drawbacks.

### Solution 2—Thin Film Processing of a Metal-VLED-Metal Stack

Rather than patterning the LED semiconductor layers and metal layers, and defining the die perimeters, from the initial top surface (e.g., p-side) of the layers prior to processing the opposite side (e.g., the n-side), both sides of the LED device can first be metallized using thin film techniques. By working with a continuous film, two-sided photolithography can be avoided, as can device surface planarity and die shifting issues. Since such defects are reduced, wafer and device yields will increase. In turn, manufacturing costs can be reduced.

The metal-semiconductor interfaces must be annealed. The innovative thin film process uses compatible annealing techniques to produce low resistance metal contacts/electrodes to both p-type and n-type surfaces. By metallizing two sides of the LED stack, a vertical current path is created.

One embodiment of the present inventions uses two different bond steps for handle wafers, and allows anode-side device layer fabrication.

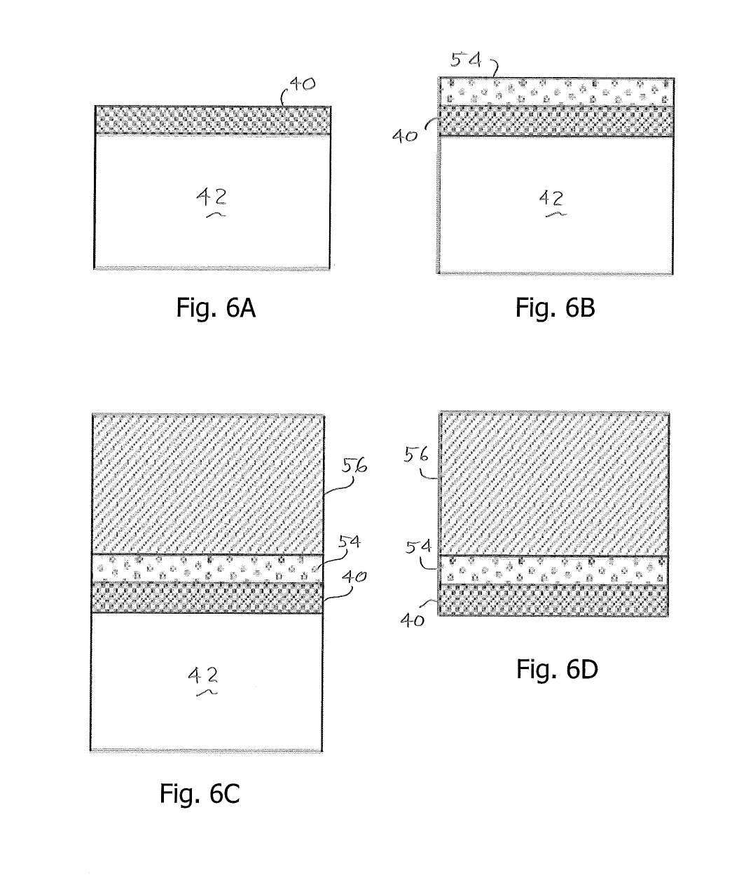

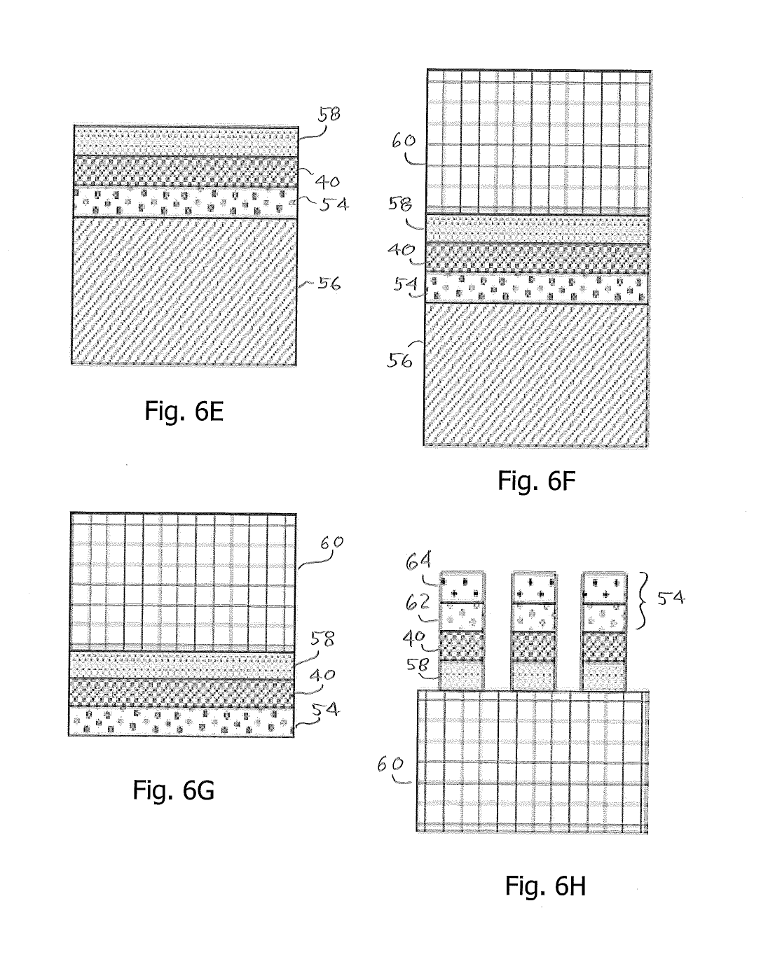

FIGS. 6A-6H are cross-sectional views of part of an LED wafer undergoing an exemplary double-bond process flow which metallizes both sides of an LED stack.

FIG. 6A shows the LED semiconductor stack 40, which includes the p-type layer, the active region, and the n-type layer, plus any buffer layers, epitaxially grown over a growth substrate 42. The p-side is facing upward.

FIG. 6B shows the metallization of the p-type layer with a metal contact layer and anode electrode layer, shown combined as the anode layers 54. The metals used may be Ni, Au, Cr, Pt, and/or ITO, where the ITO is substantially transparent to allow light to pass though.

FIG. 6C shows a first handle wafer 56 bonded to the anode layers 54 using any suitable releasable adhesive, such as silicone or other polymer, or electrostatic forces. The handle wafer 56 may be silicon, glass, or any other suitable wafer.

FIG. 6D shows the growth substrate 42 removed, such as by laser lift-off, grinding/polishing, or other means, to expose the n-type layer. The handle wafer 56 provides mechanical support after the growth substrate 42 is removed.

FIG. 6E shows the structure flipped over and the exposed n-type layer undergoing a metallization process, including deposition of the contact layer and the cathode electrode layer, shown combined as the cathode electrode layer 58.

FIG. 6F shows a second handle wafer 60 bonded to the cathode electrode 58, using a suitable adhesive that allows the first handle wafer 56 to be removed while retaining the second handle wafer 60. For example, the adhesive for the first handle wafer 56 may be dissolved by a first solution, while the adhesive for the second handle wafer 60 requires a different solution for dissolving. Such adhesives and solutions are well known. UV may also be used to release the adhesive. The adhesives used may be non-rigid to allow the LED layers and handle wafers 56/60 to have different TCE's without delamination during the thermal cycling.

FIG. 6G shows the first handle wafer 56 removed by a suitable de-bonding technique for the particular adhesive used. Note that there has been no photolithography performed up to this point.

FIG. 6H shows the device photolithographically patterned from the p-side, and the die isolation created. Die isolation may be performed by masking and etching trenches, or by sawing, or by other techniques. The p-side contact layer 62 and anode electrode layer 64 (together forming the layer 54 in FIGS. 6C-6G) are separately shown and may be patterned at the same time. The layers 62/64 are typically patterned (e.g., to form thin fingers, etc.) to allow the light to escape the p-type layer while the layers 62/64 spread current across the p-type surface for each individual LED die area. A transparent conductor may instead be used to spread the current.

Note how the cathode electrode layer 58 has been patterned, from the p-side, by the same patterning mask used to isolate the dies. The dies are typically square or hexagonal and may range from a few microns in diameter to 1 mm in diameter. There are many thousands of dies per wafer.

The patterned metal is then annealed to improve the ohmic contact, among other electrical characteristics. Annealing also serves to activate dopants in the semiconductor layers. Annealing of the metal contacts can be achieved by coordinating the thermal stability of the wafer bonding techniques and the method, magnitude, and duration of anneal. For example if the bonded second handle wafer 60 is stable at a particular temperature, then thermal annealing can be used to process the metal. Alternatively, if temperature stability is insufficient, than novel laser annealing can be used. A pulsed excimer laser has been demonstrated to anneal both p-side and n-side GaN-metal contacts. Sample parameters for the excimer pulsed anneal are 1 to 10 pulses at 450 to 550 mJ/cm² using a 248 nm excimer wavelength. The short duration of these pulses can be exploited to limit the heat transferred to the sensitive bond interface. Bonding properties can thus be specified for aspects other than temperature stability. With such bonding freedom, the number and cost of bonding steps can be reduced.

The anneal can take place before or after the metal layers are patterned. After the anneal, the dies are released from the second handle wafer 60 by a suitable process, such as dissolving the adhesive, scraping the LED dies off the wafer 60, melting the adhesive, exposure to UV, grinding down the handle wafer, or combinations or these methods or other methods described herein.

As seen from FIGS. 6A-6H, only one-sided photolithography (masking and etching) and two handle wafer bonds are used to form the vertical LEDs. Therefore, the disadvantages of two-sided photolithography are avoided.

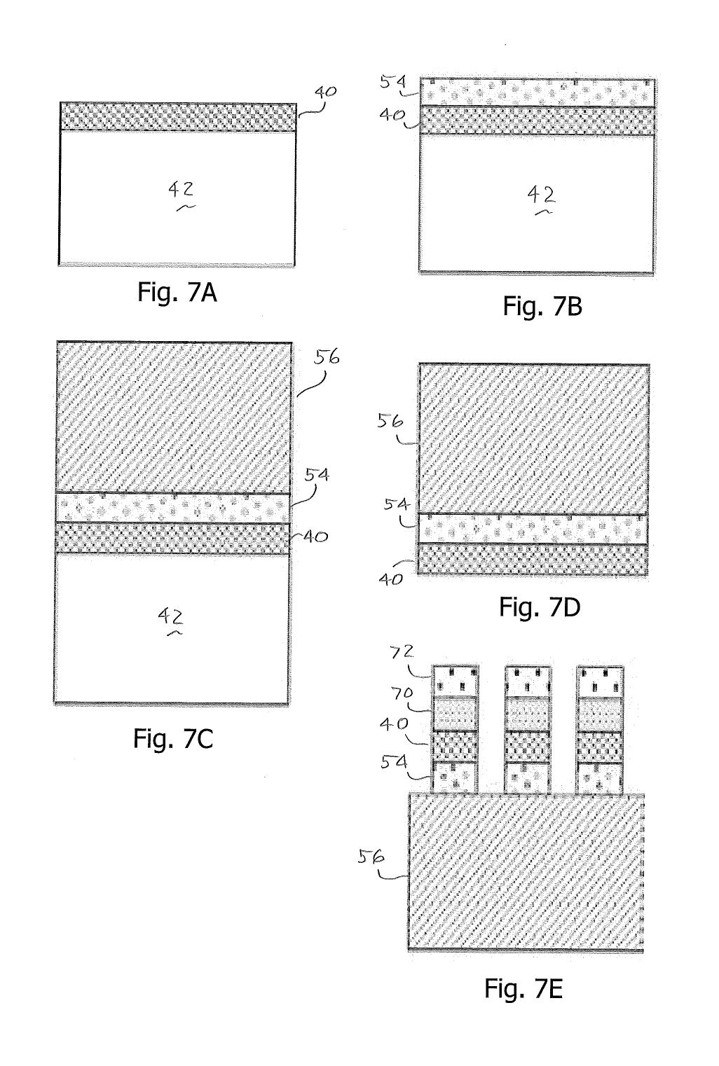

In another embodiment, shown in FIGS. 7A-7E, one-sided photolithography and a single handle wafer are used to form vertical LEDs. This embodiment uses n-side processing, rather than the p-side processing of FIGS. 6A-6H.

FIGS. 7A-7D are identical to FIGS. 6A-6D, where the growth substrate 42 is removed, along with any buffer layers, to expose the n-type layer of the LED stack 40. No photolithography is performed up to that point, and only the first handle wafer 56 is used.

FIG. 7E shows the device of FIG. 7D flipped over so the exposed n-type layer of the LED stack 40 is ready for metallization. The n-side metal contact layer 70 is deposited for good ohmic contact and to act as a diffusion barrier, followed by the cathode electrode layer 72 (configured for ultimately being connected to a power supply). The layers 70/72 may be patterned to allow light to escape the n-type layer yet still adequately spread current over the n-type layer.

After the dies are isolated (shown in FIG. 7E), such as using a masking and etching process or sawing to form trenches, the dies are released from the first handle wafer 56 as previously described. For microscopic dies, isolation is best performed by masking and etching, rather than sawing, due to the small features. For larger dies, sawing or other mechanical means may be used for isolation.

One process embodiment uses about 650 um thick, 100 mm diameter sapphire for a GaN epitaxial growth substrate. The grown GaN is on the order of 5-6 um thick, of which a quarter is a buffer, half is n-type, and the remaining quarter thickness is active, confinement and p-type layers. Metals for p-type GaN might be Ni, Au, Cr, Pt, or ITO. Metals for n-type GaN might be Ti, Al, Pt, Ni, Au or 1TO.

Annealing of the p-metals is typically performed at around 500 C. Annealing of the n-metals is typically performed at around 350 C to 550 C, though in some cases it is preferable to not anneal the n-type metal.

Materials can of course be varied, though, as there are a number of interactions of materials and process steps, one choice has an impact on other decisions. The handle wafers can be conventional wafers (e.g., silicon, glass), or can be other materials, such as epoxy, wax, or a high-density sapphire disk. For different semiconductor materials, different contact metallizations can be used as appropriate. The bonding materials may be any of those material described herein.

### Problem 3—Conventional Wafer Bonding

Conventional permanent bonds, such as anodic or conventional metal-metal, are not practically releasable. Therefore, the permanent bonds are not particularly useful for the thin film vertical LED (VLED) processing, which may require multiple bonding and de-bonding steps. Similarly, traditional temporary bonds have limited thermal stability so subsequent high temperature processing steps cannot be supported. Hence, conventional permanent and temporary bonds are limiting techniques when fabricating vertical LEDs.

### Solution 3—Thin Semi-Permanent Bonding

To enable thin film processing, innovative releasable bonding techniques are required. Such bonding techniques may be used in the above processes used to form VLEDs. A bond that is both permanent and temporary is required. This contradiction is resolved by using innovative semi-permanent bonds. One such semi-permanent bond is a thermo adhesive bond which uses a thermoplastic or thermo-set polymer, such as PMMA or BCB, as a bonding agent that can be de-bonded using an innovative thermal decomposition release. Typically, thermal decomposition of such polymers is avoided. However, in this application, thermal decomposition can be used as an advantageous de-bonding method. Semi-permanent adhesive such as PMMA can be de-bonded using other means of energy injection such as UV exposure or fusion de-bonding, which is a combination of thermal and UV exposure.

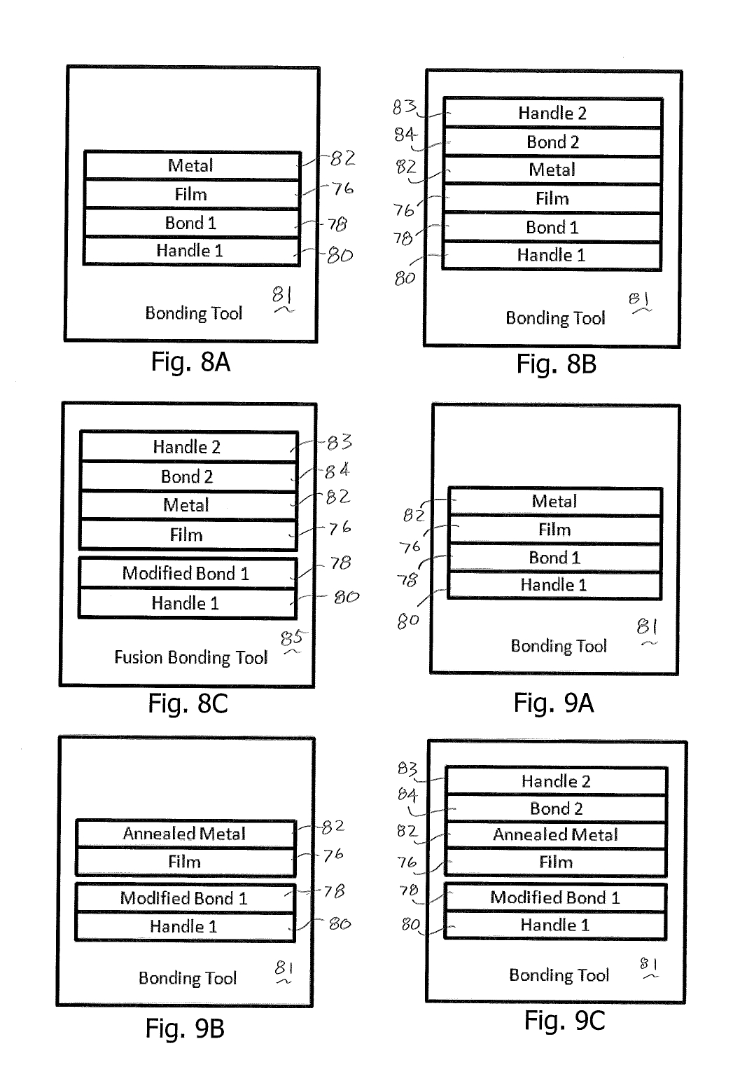

For instance, as shown in FIG. 8A, consider an LED film 76 (also referred to herein as an LED stack), where the p-side of the LED film 76 is bonded with a first thermo adhesive 78 to a first handle wafer 80 using a wafer bonding tool 81. The bonding tool 81 includes a heater and a press for applying compression to the wafers to be bonded. The bonding may take place in a vacuum to remove air between the wafers. If UV is needed decompose the adhesive, a UV source is included in the bonding tool 81. After the bonding, the growth substrate is removed from the top side, along with any buffer layers, to expose the n-type layer. The n-type surface is then metalized with the metal layer(s) 82.

In FIG. 8B, a second handle wafer 83 is bonded to the metal layer 82 using a second thermo adhesive 84. In order to then process the p-side of the LED film 76, the first handle wafer 80 must be de-bonded.

Assuming the first handle wafer 80 is transparent, such as glass, the de-bonding may be performed by a combination of thermal and UV exposure, so that the first thermo adhesive 78 is released, while the second thermo adhesive 84 remains in-tact. The metal layer 82 blocks the UV from the second thermo adhesive 84. This may be done in a fusion bonding tool 85, shown in FIG. 8C. As shown in FIG. 8C, the first handle wafer 80 is then removed. The exposed p-side surface may need to be cleaned prior to metalizing the p-side, while using the second handle wafer 83 for mechanical support.

After all processing steps, including an anneal, the LED film/metal layers are isolated by a masking and etching process or sawing to form trenches, and the isolated LED dies are removed from the second handle wafer 83, such as by a combination of heat and UV or by other means, including scraping or grinding down the second handle wafer. The second handle wafer 83 needs to pass UV light in order for UV to affect the second thermo adhesive 84. Thus, the first and second thermo adhesives 78/84 may be the same. The anneal may take place after the isolation. As seen, the two-step de-bonding process allows different bond layers to be selectively removed.

It is necessary to anneal the n-metal-semiconductor interface. FIG. 9A-9C illustrate a process that simultaneously anneals the metal and de-bonds a handle wafer. FIG. 9A shows the LED film 76 with metal layers(s) 82 over its n-type layer. The first handle wafer 80 is bonded to the p-side of the LED film 76 with a first thermo adhesive 78.

As shown in FIG. 9B, if the metalized LED stack is placed in the appropriate equipment, then the stack can be thermally annealed while simultaneously decomposing the polymer first thermo adhesive 78, de-bonding the LED film 76 from the first handle wafer 80.

As shown in FIG. 9C, the use of the appropriate equipment, such as a wafer bonding tool, allows the immediate bonding of a second handle wafer 83 via a second thermo adhesive 84. The annealed film 76 can be bonded to the second handle wafer 83 without moving the freestanding thin LED film 76. This is an important stipulation. Without an attached, rigid handle wafer, the thin film 76 is vulnerable to breakage. The novelty of annealing, de-bonding, and re-bonding in a wafer bonding tool without moving the LED stack enables safe handling.

Ultimately, such as after the LED dies are isolated, the remaining handle wafer is de-bonded, and each LED die gets adequate mechanical support from the metal layers. Various means may be used to separate the handle wafer from the metallized LED film 76 once the adhesive is dissolved/melted, such as slightly pulling the wafers apart using a vacuum clamp, a mechanical clamp, or other means.

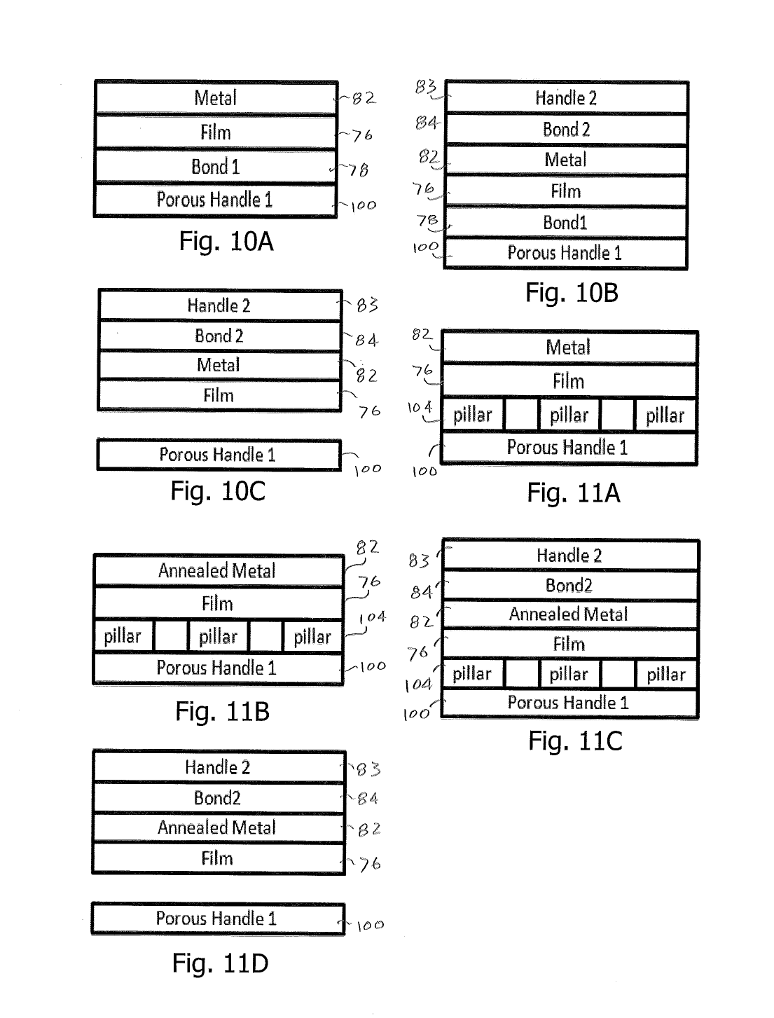

FIGS. 10A-10C illustrate the usefulness of a porous handle wafer 100. Lower temperature bonds using thermo-set and thermoplastic polymer bonds can be used if high temperature thermal annealing is not required. Thermoplastic material typically softens in excess of 200 C. Thermo-set polymers typically remain stable up to 350 C, after which thermal decomposition accelerates with temperature, so process times must be reduced accordingly. De-bonding polymers can be readily accomplished using solvents; however, this requires surface exposure. The porous handle wafer 100 can be used to expose the polymer first thermo adhesive 78 surface to a solvent applied through the porous handle wafer 100, enabling the controlled release of the LED film 76.

FIG. 10A shows the structure used for metalizing the n-layer of the LED film 76 after the growth substrate has been removed, as previously described.

FIG. 10B shows a second handle wafer 83 being bonded to the metal surface via a second thermo adhesive 84.

FIG. 10C shows the porous handle wafer 100 being removed from the LED film 76 due to a solvent being applied through the porous handle wafer 100, which dissolved the first thermo adhesive 78.

In all examples given herein, the adhesives may be cured by other than heat and may be dissolved by a solvent, UV, or by means other than heat. Therefore, the bonding adhesives do not need to be thermo adhesives.

FIGS. 11A-11D illustrate the use of pillars for de-bonding. In this embodiment, a semi-permanent bond comprises a sparse pillar metal-metal bond matrix or solder bump eutectic bond matrix which can be chemically or mechanically released. FIG. 11A shows the sparse metal pillars 104 with an air gap between the pillars 104. The metal-metal pillar embodiment uses conventional bonding metallurgy with a novel chemical release and porous handle wafer 100. The spacing of the metal pillars 104 allows the chemical etchant to flow and minimizes etch times and hence de-bonding times. The porous handle wafer 100 enables fluid transport into the pillar bond region.

In FIG. 11B, the metal layer(s) 82 are annealed.

In FIG. 11C, a second handle wafer 83 is bonded to the metal layer 82 via a second thermo adhesive 84.

In FIG. 11D, a wet metal etchant solution is applied to the porous handle wafer 100, which then enters the gaps between the pillars 104, dissolves the metal, and releases the porous handle 100 from the LED film 76. The p-side of the LED film 76 may then be processed, such as metallized. The pillars 104 may be other than metal, such as a polymer, which enable very rapid dissolving of the pillars due to the relatively small amount of polymer material verses its surface area. However, metal pillars generally withstand higher heat.

A porous handle wafer may be formed by etching or drilling holes in any suitable wafer, such as small holes spaced a few millimeters apart.

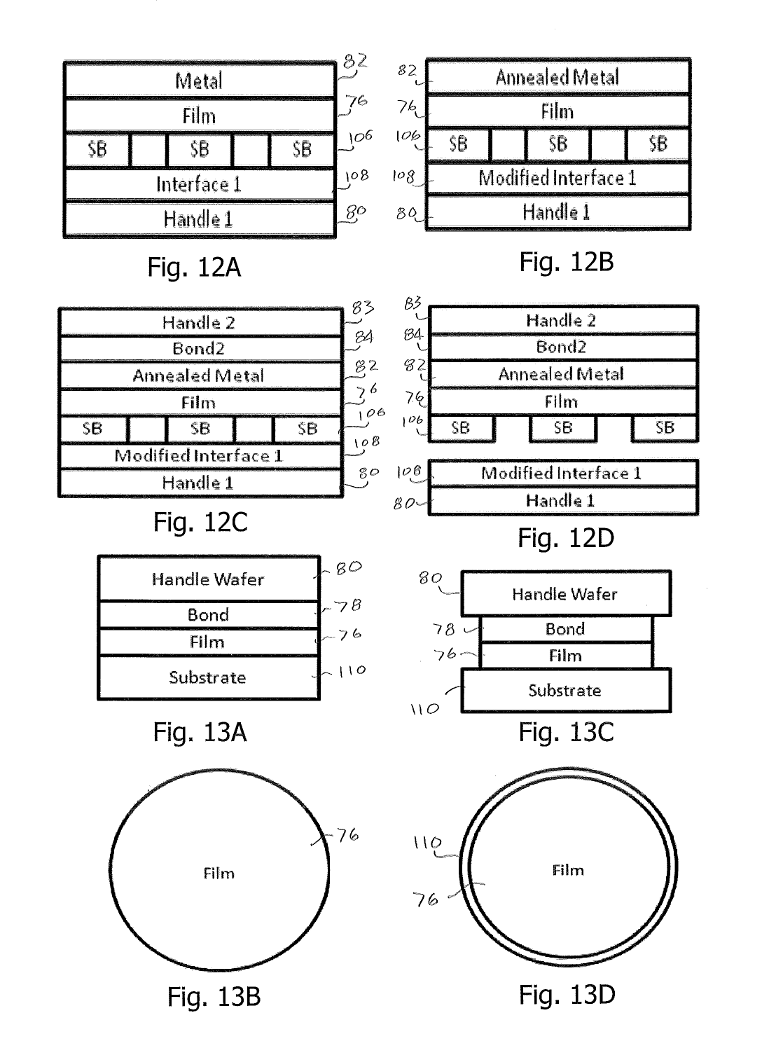

FIGS. 12A-12D illustrate an alternative bonding/de-bonding method using solder bumps 106 and a brittle interface layer instead of pillars. Conventional solder bumps 106 can be used to form a eutectic bond Like the metal pillars, the sparse placement of solder bumps 106 provides enough mechanical support for subsequent device process steps but minimizes bond area and strength, which reduces de-bonding time. An inter-metallic phase change in the interface layer, such as brittle AuAl₂ (often called purple plague), can be thermally activated during the n-type metal anneal. The brittle interface can then be easily separated by mechanical means, such as by pulling the wafers apart while twisting them. Such purple plague is known as a failure mechanism for electrical interconnections in integrated circuits. The solder bumps serve to weakly affix the brittle interface to the LED film 76.

FIG. 12A shows the metalized LED film 76 bonded to a first handle wafer 80 by means of the solder bumps 106 and the brittle interface 108.

In FIG. 12B, the metal layer(s) 82 is annealed, which greatly weakens the interface 108.

FIG. 12C shows a second handle wafer 83 bonded to the metal layer 82.

FIG. 12D shows the first handle wafer 80 being released from the solder bumps 106 by a slight pulling and twisting of the first handle wafer 80 to break the brittle bond of the interface 108. The solder bumps 108 are then removed by conventional means, and the p-side of the LED film 76 is metalized to form the vertical LEDs. The LEDs are then isolated and removed from the second handle wafer 83. As seen, the solder bumps 106 are optional if they are not needed to bond the interface 108 to the LED film 76.

FIGS. 13A-13D illustrate a de-bonding technique using edge trimming. The quality of the bond near the edge of the wafer is problematic. The LED film 76 tends to thin as it extends toward the growth substrate edge, which increases total thickness variation leading to a weak region after bonding. Secondly, the bond edge is exposed near the edge, which makes the bond susceptible to peeling. And lastly, subsequent processing after bonding is commonly uncontrolled near the wafer edge, so uniformity is reduce near the edge which can also lead to delamination. To overcome these edge issues, the LED film can be trimmed near the edge. Trimming can be accomplished by various means such as etching or mechanical grinding or sawing. Additionally, the bond layer can be selectively removed at the edge as well. By avoiding bonding near the wafer edge, uniformity increases and peeling is less likely.

FIG. 13A shows the LED film 76 on the growth substrate 110 (e.g., sapphire), where the LED film 76 is attached to a first handle wafer 80 via a first thermo adhesive 78. Ultimately, the substrate 110 will be removed for metalizing the exposed n-layer of the LED film 76, as previously described.

FIG. 13B shows a top down view of the LED film 76 on the substrate 110.

FIG. 13C shows the etching away of the edge of the LED film 76 and the first thermo adhesive 78, so that the LED film 76 and first thermo adhesive 78 are uniformly thick and the bond is uniformly strong across the LED film 76.

FIG. 13D is a top down view of the LED film 76 showing how the film 76 is etched away from the edge of the substrate 110. The structure is then processed using any of the techniques described above for metallization and patterning to form individual vertical LEDs.

### Problem 4—LED Film—Substrate Removal

In order to expose the n-type surface of the LED stack, a selective, high yield and cost-effective separation technique for the growth substrate is required. Obvious mechanical methods such as grinding, lapping, and polishing can be cost-effective if sufficient removal rates are achieved. However, the conventional mechanical methods lack selectivity. For example, the polish rate of GaN can exceed the rate of sapphire. Therefore if the polish plane is not parallel to the LED film-substrate interface, then the uneven polish will begin to remove LED film in some areas before completely removing all of the substrate material. A hybrid polish and etch is also not selective, because sapphire etch rate is commonly much slower than GaN.

Optical removal methods such as laser ablation, also known as laser lift-off (LLO), can be used to separate GaN from sapphire. However, LLO uses pulse lasers with a confining aperture. This exposure aperture is stepped across the wafer surface, discretely releasing the GaN from sapphire. This method of laser stepping causes issues at the boundary of each field of view. Overlapping laser pulses can damage the GaN film. While under-exposure at the boundary can fail to separate the GaN and cause cracking when the sapphire is removed.

Other removal techniques include thermal or mechanical spalling (forced peeling and cracking). Both techniques use fracture mechanics to propagate a crack laterally at some depth in the LED film. Control and yield of such a process can be unpredictable. Thermal spalling can require excessive temperature deviation to create enough stress to initiate a crack. Such temperatures may damage the LED film or carrier substrate. Similarly mechanical spalling has difficulty initiating a crack at the desired depth in the film.

### Solution 4—Novel Substrate Removal

The short comings of crack initiation for mechanical spalling can be resolved by properly conditioning the edge of the LED film. For instance the LED film can be etched, sawn, or by other means processed to create a shaped sidewall. Such a sidewall directs the mechanical stress of the peeling toward the interface of the LED film and the substrate.

Stress thus builds at the base, causing a crack to initiate which, if properly constrained, will propagate laterally along the interface. Additionally, the sawn sidewall preparation can be paired with modifying the shape of the LED wafer, maximizing the number of smaller wafers that can be tiled on a larger wafer, as previously discussed with respect to FIG. 1.

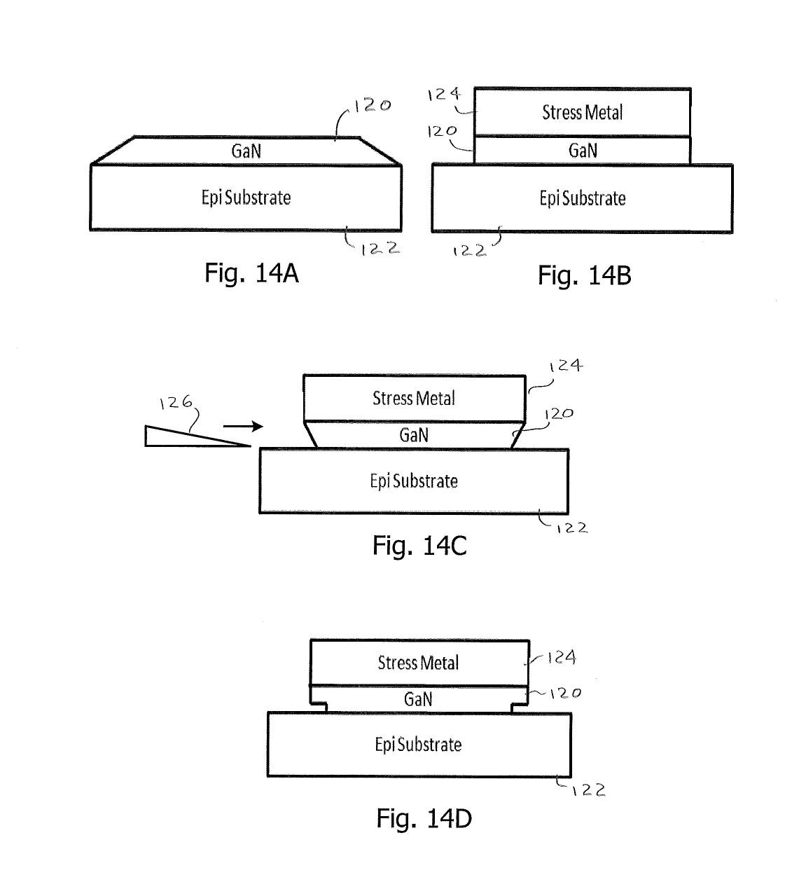

FIG. 14A shows a GaN layer 120 epitaxially grown on a growth substrate 122, such as a sapphire wafer. The GaN layer 120 forms an LED stack, previously described, and is very thin and brittle. Note how the GaN layer 120 has thin edges due to inherent properties in the epitaxial growth process. Since the GaN edge is angled upward, inserting a spalling blade near the GaN/substrate interface is difficult, and the separating spalling pressure is not directed at the interface. Also, the thin GaN edge is most likely to crack arbitrarily, and the crack will propagate laterally.

FIG. 14B shows a stress metal layer 124 deposited over the GaN layer 120. This stress metal layer 124 can be the p-side metallization of the LED stack to give the GaN layer 120 mechanical support during the spalling process to reduce the risk of vertical cracking. The GaN layer 120 and stress metal layer 124 are then etched to pull the GaN layer 120 back from the edge of the substrate 122, such as by using Reactive Ion Etching (RIE).

FIG. 14C shows the GaN layer 120 undercut by using a wet etch. A thin spalling blade 126 is then moved across the GaN/substrate interface to promote cracking along the interface to separate the GaN layer 120 from the substrate 122. The angled edge of the GaN layer 120 directs the sharp edge of the spalling blade 126 to the interface so all separating energy is focused at the interface. Therefore, the cracking is likely to propagate laterally at the interface to remove the GaN layer 120 from the substrate 122.

FIG. 14D shows the GaN layer 120 cut, such as by sawing, near the interface, rather than etched. The edge of the spalling blade 126 is thus directed by the cut to the GaN/substrate interface, so the cracking will occur along the interface and propagate laterally to remove the GaN layer 120 from the substrate 122.

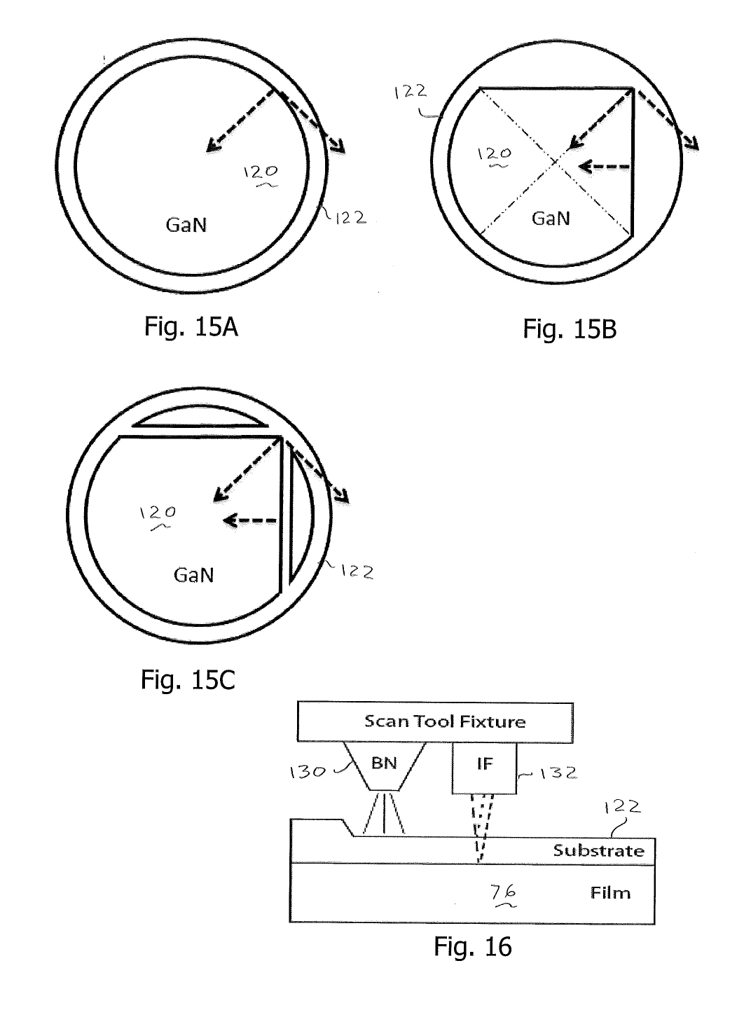

Additionally, the GaN preparation steps prior to spalling can be coordinated with the bonding preparation. For instance, as shown in FIGS. 15A-15C, if multiple smaller diameter LED wafers are to be bonded to a larger carrier wafer (described with respect to FIG. 1) and the LED wafers are to be shaped prior to bonding to the carrier wafer, then the shape of the GaN film can be also modified to be optimized for the spalling process. The spalling can occur before the LED wafers are shaped and bonded to the carrier wafer.

FIG. 15 A is a top down view of the GaN layer 120 having its edge etched back from the edge of the sapphire substrate 122 prior to spalling (described with respect to FIGS. 14C and 14D. In that case, there is high local biaxial stress at the edge during spalling, as shown by the dashed force lines, increasing the likelihood of cracking along undesired planes.

FIG. 15B shows the GaN layer 120 being shaped, like in FIG. 1, for tiling four LED wafers on a single carrier wafer. The spalling can start at the corner or, more preferably, along a flat edge of the GaN layer 120. If the spalling begins along the flat edge, there is uniaxial stress and less likelihood of cracking along undesired planes.

FIG. 15C is similar to FIG. 15B but only a section of the GaN layer 120 is removed prior to spalling along the flat edge of the GaN layer 120.

After spalling to remove the GaN layer 120 from the substrate 122, the shaped GaN layer 120 is bonded to the carrier wafer, along with three identical GaN layers, for processing to form vertical LEDs, as described herein.

Alternatively, a novel mechanical ablation of sapphire can be achieved using in-situ thickness measurement, as shown in FIG. 16. FIG. 16 shows a sapphire growth substrate 122 undergoing a removal process. The bottom surface of the LED film 76 is supported by a handle wafer (not shown). First, the sapphire substrate 122 is rapidly thinned using conventional grinding methods. Grinding is halted when the uncertainty of the remaining sapphire thickness exceeds the confidence in the total thickness variations in the underlying LED film 76, bond layer, and handle wafer. The thinned stack is placed in a novel mechanical ablation chamber, shown in FIG. 16. The remaining sapphire substrate 122 is removed by a selective technique that uses a constant or periodic in-situ thickness measurement in a closed loop with a mechanical ablation tool. In the example of FIG. 16, a sand blasting tool expelling appropriately sized media, such as Al₂O₃, from a blast nozzle 130 can quickly remove the remaining sapphire material. Blasting alone lacks selectivity for sapphire over GaN. An in-situ thickness measurement, for example by using an interferometer 132, is used in a closed loop blasting control system, to constantly or periodically measure the thickness of the sapphire. The sand blasting is stopped when the measurement detects a zero thickness of the sapphire. An optical thickness measurement using the interferometer 132 can be easily achieved, since the index of refraction of GaN is considerably higher than that of the sapphire substrate. Therefore, when there is a sudden change in the detected index, it conveys that the sapphire is gone.

The sandblasting and thickness measurement may be performed as the wafer is moved back and forth under the nozzle 130, with each pass removing only a small thickness of the substrate 122.

Alternatively, if the sandblasting is done over the entire surface of the wafer, the interferometer 132 only needs to detect the index of refraction of a small area of the wafer. If the sandblasting is not precisely uniform, the interferometer 132 would be directed to the area which is the last to have the sapphire removed from.

After the sandblasting, a finer polishing or sandblasting can be done to remove any GaN buffer layer to expose the n-type layer of the LED film 76.

Finally, if sufficient compliance and selectivity exist between abrasively removing the substrate 122 versus the film 76, then a finer mechanical grind or polish can be sufficient for removing the entire substrate 122, rather than sandblasting.

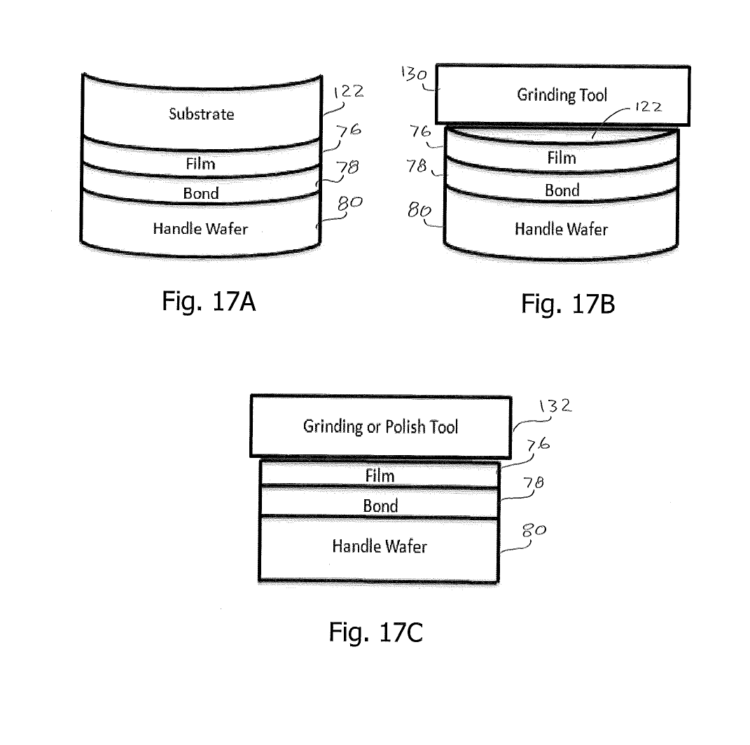

FIGS. 17A-17C show such grinding to remove the growth substrate 122 while the LED film 76 is bonded to a first handle wafer 80. FIG. 17A shows that there is some curvature to the structure, such as due to the thinness of the various layers and curvature due to CTE mismatch or other forces.

FIG. 17B shows the substrate 122 being ground down by a flat grinding tool 130 to the raised edges of the LED film 76, leaving some of the substrate 122 remaining over the center area.

FIG. 17C shows a finer grinding/polishing tool 132 being used to remove the remainder of the substrate 122 while finely planarizing the top of the LED film 76 to expose the n-type layer for metallization.

### Problem 5—Light Emission Directionality

The surface from which the vertical LED emits light (p-side or n-side) constrains the package in which it can be placed. This directionality limits materials and performance and can increase overall cost, unless the direction can be selected arbitrarily. For instance for p-type surface emission, a reasonably thick optically transmissive conductive layer is typically required for lateral current spreading over the p-type layer and uniform current injection. However, this thick conductive layer also absorbs some light, which reduces overall efficiency. This current spreading layer also adds cost to the process. Alternatively, an n-type surface emitter may require additional processing steps to expose the n-type surface. And finally, since most LED devices are Lambertian emitters, most of the emitted optical power is directed vertically, which requires complicated and potentially inefficient secondary optics (e.g., lenses) to achieve spatial diffusion. Diffuse light sources are generally preferred for lighting, because high contrast glaring sources are disturbing.

### Solution 5—Process Definable Directionality

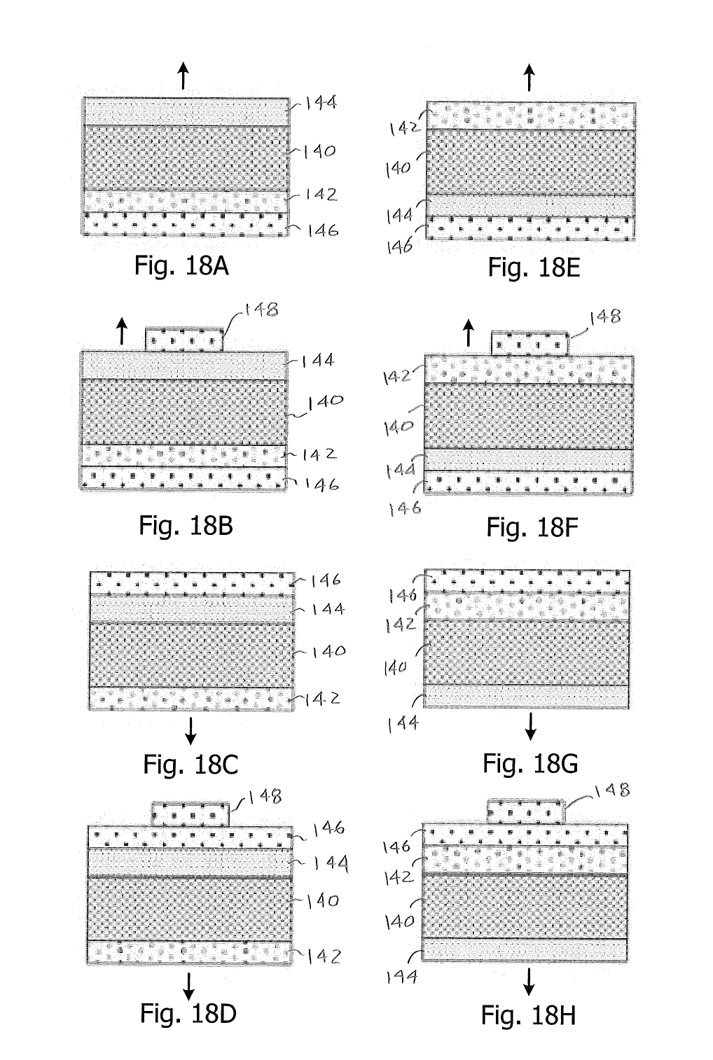

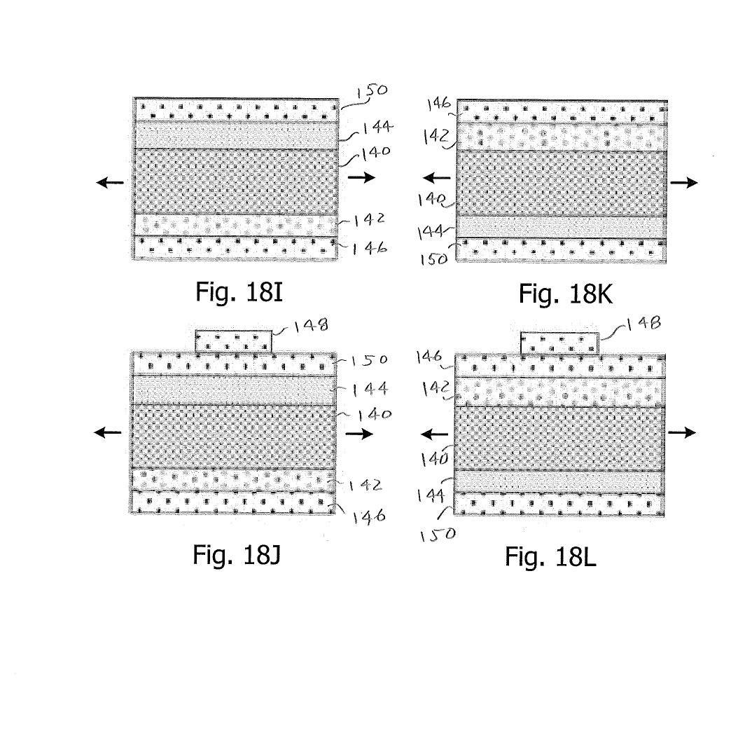

FIGS. 18A-18L relate to selecting the light emission side of a vertical LED.

The nature of processing the LED film using the inventive bonding techniques allows the final orientation of the emitting surface to be defined. Essentially, the LED film can be flipped back and forth between handle wafers until the desired light emitting device surface is exposed. Once the desire surface is exposed, the device layers are patterned and the device is completed. This process flexibility is novel to the thin film VLED methodology.

Some possible vertical LED configurations are shown in FIGS. 18A-18L. The light can be emitted from either the anode surface or the cathode surface. The device can be oriented with either the anode or the cathode upward facing (away from the package base). The device can be fabricated with or without a metal bump contact. The bump provides a thick contact feature (for connection to a power source) which is often useful for printable devices.

The directionally of the LED emission is defined by the location of reflecting and transmissive surfaces. The reflecting layer can be a silver layer or an alloy that conducts current and reflects greater than 90% of visible light. The reflective metal layer may be deposited by printing, sputtering, evaporation, or other means.

Transmissive surfaces can be insulating or conductive. These extraction surfaces can also be patterned or textured to improve transmission despite a high disparity between indices of refraction, for example, between GaN and air.

Metal, oxide, nitride or other materials can be used as reflective surfaces on the side opposite to the emission side, whether the surface is reflective in itself (e.g., a reflective metal) or the surface reflects by total internal reflection (TIR) due to index mismatch at the interface. Such minors can be deposited on the p-side surface for an n-side emitter, on the n-side surface for a p-side emitter, or on both the p-side and n-side surfaces for a sidewall emitter. Dual minors are commonly used in laser devices as confinement boundaries. Since LEDs are Lambertian emitters, the intense normal emission is difficult and inefficient to spatially diffuse using secondary optics. The side emitting LED, using dual mirrors, emits intense light perpendicular to the conventional normal surface. This side emission is easier to spatially diffuse.

FIGS. 18A-18L illustrate various configurations of the LED with and without the bump. The side opposite the emission surface is coated with an opaque reflective metal that also conducts the vertical current, and the emission surface conductive layer may be a patterned metal that lets light escape and spreads current or may be a transparent conductor. The directionality can thus be determined by only minor variations to the metallization/conductor process, without affecting the LED semiconductor layer process.

In FIGS. 18A-18L, the elements are labeled as follows: LED semiconductor stack (or film) 140 having a p-side and an n-side; p-side contact layer 142, n-side contact layer 144, first metal mirror layer 146, metal bump contact 148, and second metal mirror layer 150. The direction of light emission is shown by an arrow.

FIGS. 18A and 18B show a VLED with a cathode emitter and the cathode up.

FIGS. 18C and 18D show a VLED with an anode emitter and the cathode up.

FIGS. 18E and 18F show a VLED with an anode emitter and the anode up.

FIGS. 18G and 18H show a VLED with a cathode emitter and the anode up.

FIGS. 18I and 18J show a side-emitting VLED with the cathode up.

FIGS. 18K and 18L show a side-emitting VLED with the anode cathode up.

### Methods of Manufacturing—Single Bond VLED

The preferred method of manufacture of a vertical LED uses a single handle wafer bond to create the vertical LED. The single bond VLED requires low temperature processing.

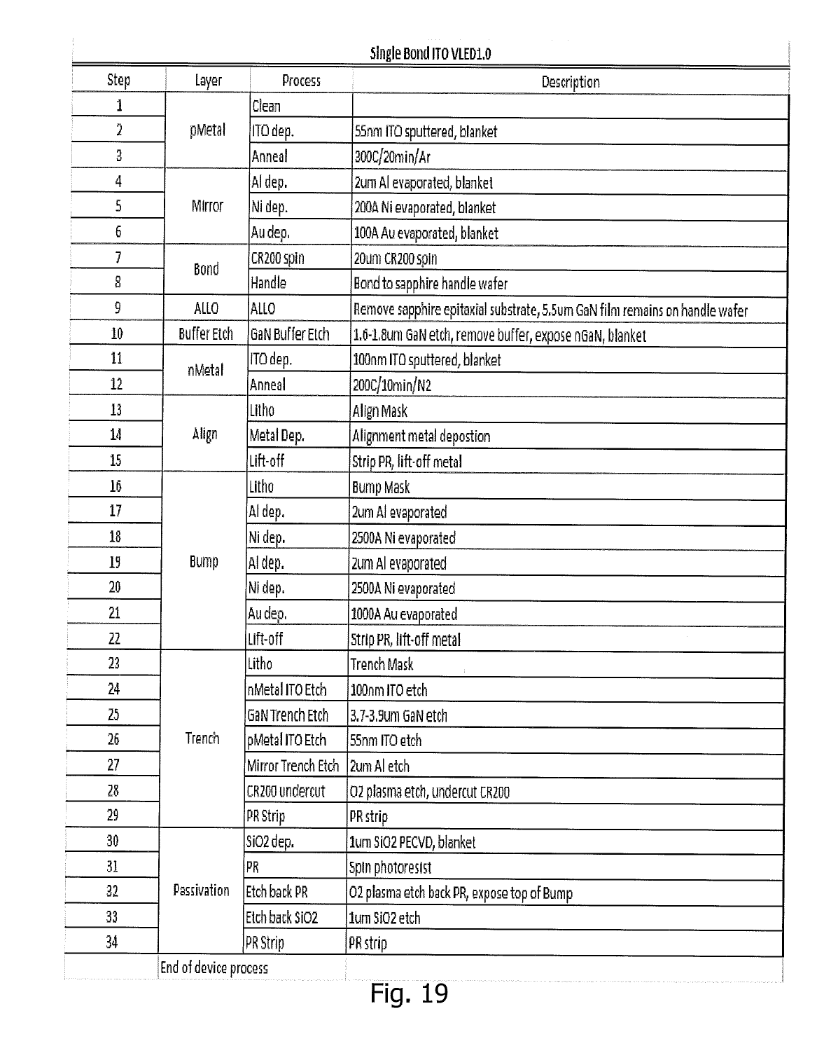

Indium-tin-oxide (ITO) has been shown to provide excellent electrical and optical performance for current spreading and for allowing light to pass through and is suitable for both p-type and n-type contact to GaN at sufficiently low annealing temperatures. As such, a Single Bond ITO VLED process is listed in FIG. 19 assuming a 5.5 um GaN film on sapphire. FIG. 19 is self-explanatory.

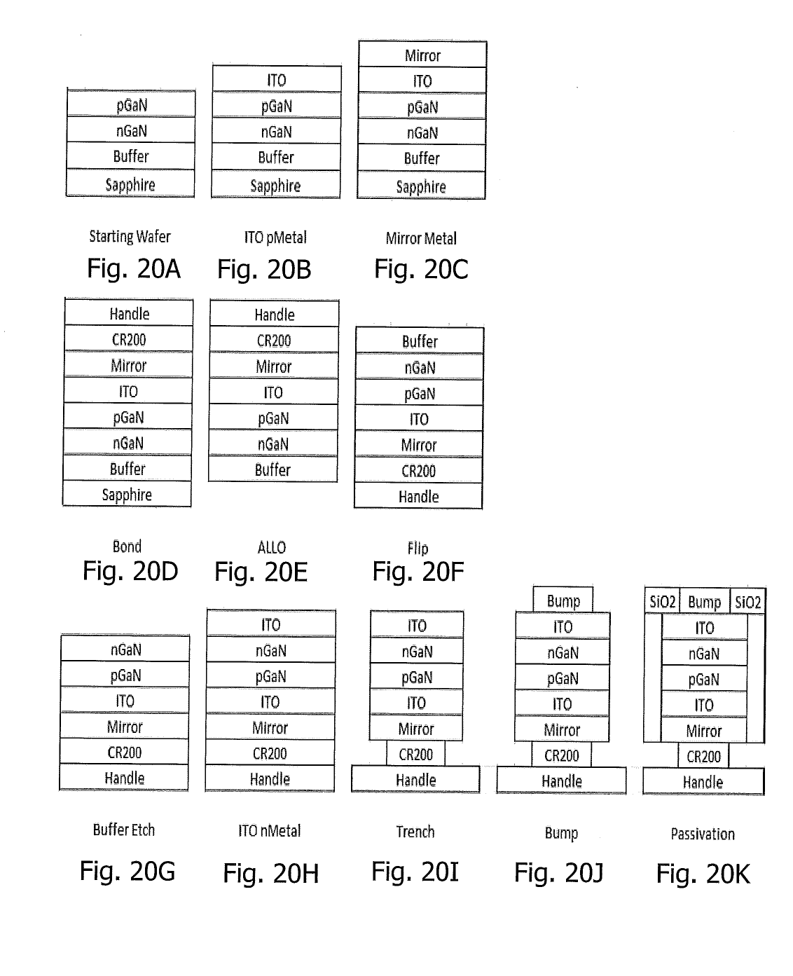

FIGS. 20A-20K schematically illustrate the various layers of the VLED structure at various stages of the process of FIG. 19. FIGS. 20A-20K are self-explanatory.

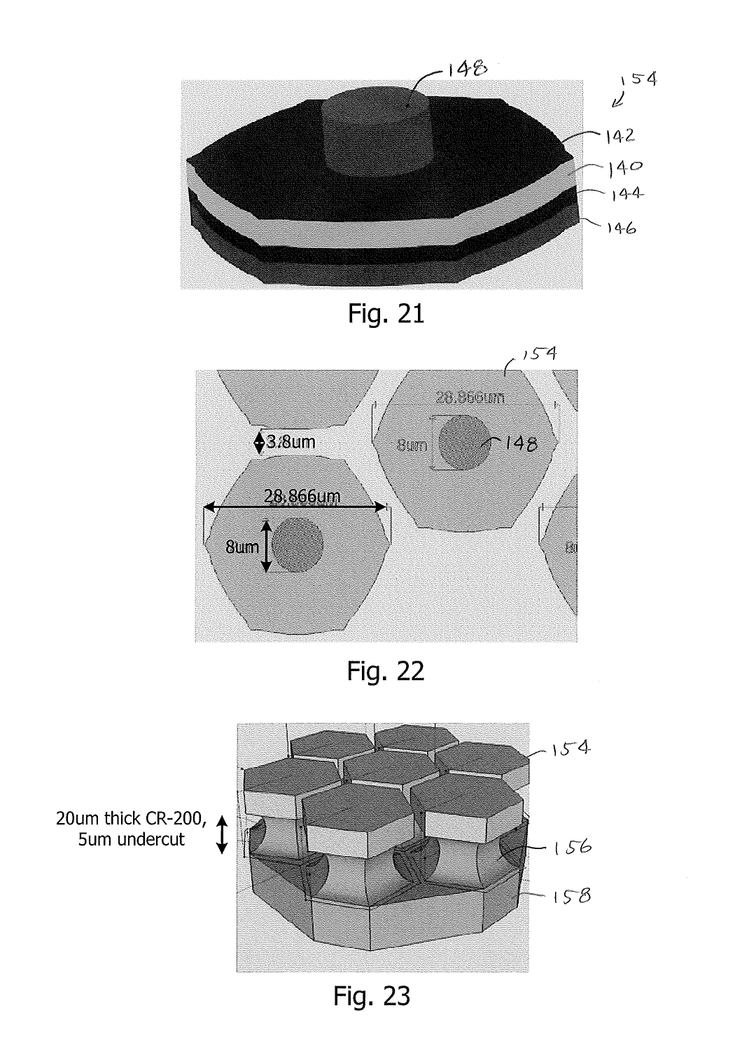

FIG. 21 is a perspective view of a singulated hexagonal VLED 154 that may be formed using any of the above processes. The VLED 154 is shown having a bump contact 148. It may have a cathode emission surface or an anode emission surface. In the example, the VLED 154 is an anode emitter with the p-side contact layer 142 on top of the LED film 140, the n-side contact layer 144 on the bottom of the LED film 140, and a mirror layer 146 on back of the n-side contact layer 144. The VLED 154 has a diameter of about 29 microns and may be printed as an LED ink to form a sheet of distributed VLEDs. The solvent in the ink is evaporated by heat, leaving the VLEDs on a conductive substrate, such as a sheet of metal foil. An anneal may be performed to electrical bond the bottom electrode to the substrate, and a transparent conductor is used to contact the top electrode. Groups of the VLEDs are thus electrically connected in parallel. Phosphor may be deposited over the surface to create a multi-wavelength emission such as white light, where the blue light from the VLED leaks through the phosphor layer, and the phosphor layer contributes red and green components.

FIG. 22 is a top down view of the VLEDs 154 after an isolation (trench) etch to form VLED islands, and FIG. 23 is a perspective view of the structure of FIG. 22. Dimensions are identified in the figures. The VLEDs 154 are shown still weakly bonded to the undercut bonding material 156 connecting them to the handle wafer 158 after a bond dissolving/etching process. The bonding material 156 may be WaferBOND CR-200 (a polymer) by Brewer Science, Inc. The bonding material is spun-on. The bonding material 156 may be undercut with an O₂ plasma etch or removed with a remover solution supplied by Brewer Science, Inc. Even if a passivation layer is deposited over the VLEDs 154, the gaps between the VLEDs 154 will make the passivation layer discontinuous to allow the VLEDs 154 to be separated from one another. To separate out the VLEDs 154, the handle wafer 158 may be ground down until the VLEDs 154 are separated, and the VLEDs 154 are uniformly dispersed in a solvent for being printed on a substrate as an ink. Alternatively, the bonding material 156 is completely etched or dissolved to release the VLEDs 154.

Further detail of forming a light source by printing the microscopic VLEDs 154 can be found in US application publication US 2012/0164796, entitled, Method of Manufacturing a Printable Composition of Liquid or Gel Suspension of Diodes, assigned to the present assignee and incorporated herein by reference.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A method of manufacturing vertical light emitting diodes (VLEDs), comprising:
providing a handle wafer and a group of LED wafers, wherein a diameter of the handle wafer is greater than the diameter of each or the LED wafers;
bonding the group of LED wafers to a surface of the handle wafer; and
processing the group of LED wafers simultaneously to form VLEDs.

2. The method of claim 1 further comprising:
modifying the shape of the LED wafers, by removing areas from each of the LED wafers, to form shaped LED wafers;
bonding the shaped LED wafers to the surface of the handle wafer prior to the step of processing the group of LED wafers.

3. The method of claim 2 wherein, prior to modifying the shape of the LED wafers, the LED wafers are substantially circular, and wherein modifying the shape of the LED wafers comprises removing areas from each of the LED wafers to form an angular corner of each of the LED wafers,
wherein bonding the shaped LED wafers comprises locating the corners of the LED wafers proximate to a center of the handle wafer such that opposing sides of adjacent LED wafers substantially abut each other on the handle wafer.

4. The method of claim 3 four LED wafers are bonded to the handle wafer, wherein the shaped LED wafers each have a substantially 90 degree corner and straight sides extending from the corner, and wherein the straight sides of the adjacent LED wafers on the handle wafer substantially abut each other.

5. A method for fabricating vertical light emitting diodes (VLEDs), comprising:
providing a handle wafer;
epitaxially growing a semiconductor material having at least a p-type semiconductor anode layer and an n-type semiconductor cathode layer;
forming a first metallization layer and a second metallization layer on opposite surfaces of the semiconductor material, using the handle wafer for support of the semiconductor material during at least forming one of the first metallization layer and the second metallization layer, the handle wafer being affixed to the semiconductor material by a bonding material;
photolithographically patterning the semiconductor material, the first metallization layer, and the second metallization layer to thereby separate portions of the semiconductor material into separate islands attached to the handle wafer; and
removing the handle wafer from the semiconductor material, the first metallization layer, and the second metallization layer to provide individual, physically separate VLEDs.

6. The method of claim 5 further comprising:
forming the first metallization layer on an exposed first side of the semiconductor material prior to removal of a growth substrate;
bonding the handle wafer to the first metallization layer;
removing the growth substrate to expose a second side of the semiconductor material;
forming the second metallization layer on the exposed second side of the semiconductor material; and
performing the step of photolithographically patterning the semiconductor material, the first metallization layer, and the second metallization layer to thereby separate portions of the semiconductor material into separate islands attached to the handle wafer, wherein the first metallization layer is not photolithographically patterned prior to the step of photolithographically patterning.

7. The method of claim 6 wherein removing the handle wafer comprises:
etching trenches in the semiconductor material to form the separate islands during the step of photolithographically patterning; and
removing the bonding material between the islands.

8. The method of claim 7 further comprising grinding down the handle wafer until the VLEDs are physically separated from each other.

9. The method of claim 7 further comprising removing the bonding material from under each of the islands until the VLEDs are physically separated from each other.
